(19) United States
(12) Patent Application Publication
(10) Pub. No.: US 2026/0343789 A1
(43) Pub. Date: Oct. 29, 2026

(54) HEAT DISSIPATION STRUCTURE IN A POWER SUPPLY UNIT TO IMPROVE HEAT DISSIPATION EFFICIENCY

(71) Applicant: Aivres Systems Inc., San Jose, CA (US)

(72) Inventor: ChiWen CHIANG, New Taipei City (TW)

(21) Appl. No.: 19/193,931

(22) Filed: Apr. 29, 2025

(51) Int. Cl. H05K 7/20; G06F 1/20

(52) U.S. Cl. CPC H05K 7/20145; G06F 1/20; H05K 7/20172; H05K 7/20909

(57) ABSTRACT

A power supply unit (PSU) is disclosed, including a housing with an air inlet and outlet, and a mid-section narrowed relative to adjacent upstream and downstream sections. This reduced cross-sectional area accelerates the airflow, directing it more effectively onto at least one heat-generating component located within or near the mid-section. The resulting increased airflow velocity enhances thermal management by quickly removing heat, allowing the PSU to operate more efficiently and potentially use lower-speed fans.

### TECHNICAL FIELD

The present invention relates to power supply unit (PSU) design, specifically to an improved internal structure that enhances heat dissipation efficiency.

### BACKGROUND

Power supply units (PSUs) are critical components in electronic systems, responsible for converting and regulating electrical energy to power various devices. As modern electronic systems demand higher power densities, efficient thermal management becomes essential to ensure reliability and longevity. Conventional PSU designs typically employ rectangular or cuboid enclosures, which allow incoming air to distribute evenly across the internal space. However, such designs fail to focus airflow on high-temperature areas, resulting in suboptimal cooling performance and increased thermal stress on key components.

Existing PSUs rely on fans to circulate air, but the uniform distribution of airflow within a rectangular enclosure does not adequately address localized heat generation. The inefficiency of such cooling methods can lead to overheating, component degradation, and energy wastage due to the need for larger or higher-speed fans to compensate for inadequate heat dissipation.

### SUMMARY

A system of one or more computers can be configured to perform particular operations or actions by virtue of having software, firmware, hardware, or a combination thereof installed on the system. When in operation, these elements cause the system to perform specific actions. Similarly, one or more computer programs can be configured to perform particular operations or actions by including instructions that, when executed by data processing apparatus, cause the apparatus to perform those actions.

In one general aspect, a power supply unit (PSU) may include a housing defining an air inlet for receiving cooling air and an air outlet for expelling heated air. The PSU housing may include a mid-section with a reduced cross-sectional area relative to the adjacent upstream and downstream sections of the housing. This reduced cross-sectional area accelerates the airflow passing through the mid-section. The PSU may also include at least one heat-generating component positioned within or proximate to the mid-section to receive the accelerated airflow for enhanced cooling. Other embodiments of this aspect include corresponding computer systems, apparatuses, and computer programs recorded on one or more computer storage devices, each configured to implement the described structures.

Implementations may include one or more of the following features: a PSU where the mid-section is formed by an internal partition or a contoured structure within the housing to create the reduced cross-sectional area for the airflow; a PSU where the mid-section is formed by a molded structure integrated into the housing during manufacturing; and a PSU where the housing has an external shape that is substantially rectangular or cuboid.

The PSU may include a fan configured to generate the airflow through the housing. In some implementations, the fan operates at a reduced speed due to the accelerated airflow within the mid-section. The accelerated airflow reduces cooling demands, enabling quieter and more energy-efficient operation while maintaining thermal conditions within a safe range inside the housing.

The PSU may also include a transition section from the adjacent upstream section to the mid-section. This transition section may feature a tapered structure with a smooth and continuous slope, configured to gradually narrow the cross-sectional area of the airflow to minimize turbulence and improve aerodynamic efficiency, thereby reducing pressure loss and optimizing airflow velocity.

The tapered structure defining the transition section may have a conical shape with a circular cross-section that gradually narrows toward the mid-section. Alternatively, the tapered structure may have a trapezoidal or frustum shape with a rectangular cross-section that narrows toward the mid-section.

The PSU may further include a transition section from the mid-section to the adjacent downstream section. This transition section may feature an expanding structure with a smooth and continuous slope that gradually increases the cross-sectional area to facilitate airflow diffusion, reduce backpressure, and enhance heat dispersion efficiency.

Implementations of the described techniques may involve hardware, a method or process, or a computer-readable tangible medium.

In another general aspect, the present disclosure provides a housing for a power supply unit (PSU) that enhances internal cooling performance through geometric airflow optimization. The housing includes an air inlet at a first end for receiving cooling air and an air outlet at a second end for expelling heated air. Between these ends, the housing defines an upstream section, a downstream section, and an intermediate mid-section. The mid-section has a reduced cross-sectional area that is smaller than that of both the upstream and downstream sections, forming a narrowed airflow path. This constriction accelerates the velocity of the cooling air as it passes through the mid-section, thereby improving convective heat transfer in that region. The structural configuration enables more efficient cooling of internal components, particularly those positioned near the mid-section, without requiring increased fan speed or added mechanical complexity.

Other embodiments of this aspect include corresponding computer systems, apparatuses, and computer programs recorded on one or more computer storage devices, each configured to perform the described methods.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 illustrates some example Power Supply Units (PSUs).

FIG. 2 illustrates an example thermal field image inside a PSU.

FIG. 3 illustrates a plurality of airflow guiding structures inside a PSU for improving heat dissipation efficiency inside the PSU, according to one example embodiment.

FIG. 4 illustrates an example airflow guiding structure inside a PSU for improving heat dissipation efficiency over key heat-generating components, according to one example embodiment.

FIG. 5 illustrates another example airflow guiding structure inside a PSU for improving heat dissipation efficiency over key heat-generating components, according to one example embodiment.

FIG. 6 illustrates an example manufacturing process of the PUS, according to one example embodiment.

FIG. 7 illustrates a block diagram of an example computer system in which various of the embodiments described herein may be implemented.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

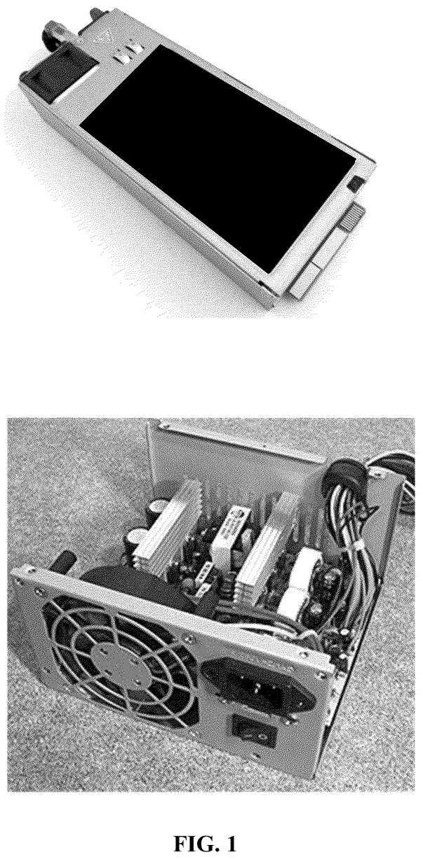

FIG. 1 illustrates some example Power Supply Units (PSUs) commonly used in electronic systems.

A PSU is a critical component responsible for converting electrical power from an external source, such as alternating current (AC) from a wall outlet, into the direct current (DC) required by various internal components of a device. Effective cooling or heat dissipation is essential for PSUs to ensure consistent performance, prevent overheating, and extend the lifespan of sensitive electronic components. Inefficient cooling can lead to thermal stress, reduced operational efficiency, and, in extreme cases, system failure. Heat dissipation in a PSU is typically achieved through mechanisms such as internal fans that generate airflow, passive heat sinks, or a combination of both. Fans play a pivotal role by drawing cooler air into the PSU, directing it over the internal components, and expelling the heated air through vents.

PSUs used in computing-intensive devices, such as servers, gaming systems, AI-driven systems, crypto-mining systems, and other types of high-performance workstations, generate significantly more heat than those used in standard consumer electronics. This increased heat production arises from several factors. First, computing-intensive devices draw more power due to the increased workload, placing greater demands on the PSU. As the power consumption rises, the PSU generates more heat as a byproduct of its internal processes. The conversion of AC to DC power, which is the primary function of the PSU, inherently produces heat as energy is lost during the conversion process. The more power that needs to be converted, the greater the heat output.

Additionally, as computing-intensive applications push processors, graphics cards, and other components to their thermal design power (TDP) limits, the PSU must work harder to meet these increased power demands. This amplifies internal heat generation and places further stress on the PSU's internal components. The PSU must be able to sustain this increased power output while managing the higher thermal loads to maintain safe operating temperatures.

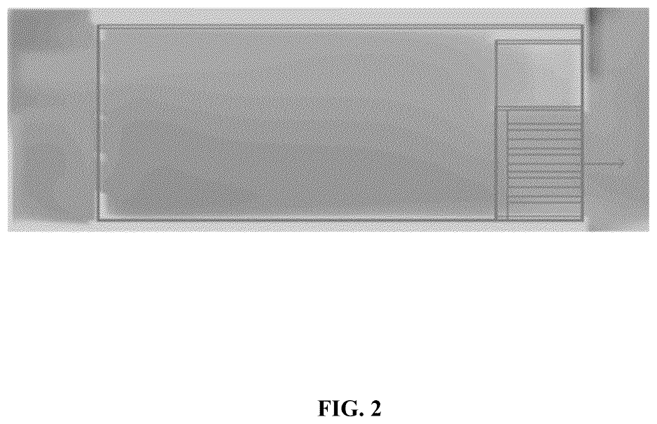

FIG. 2 illustrates an example thermal field image inside a PSU, providing a visual representation of the heat distribution within a conventional power supply unit. As depicted, the thermal field highlights regions of elevated temperature, corresponding to the locations of key heat-generating components, such as power conversion modules, voltage regulators, and capacitors. In the absence of an optimized internal airflow path, these high-temperature areas are insufficiently cooled, as the airflow passes uniformly through the cuboidal or rectangular housing without any directional focus. The heat map in FIG. 2 reveals how the uniform airflow results in “hot spots” where heat accumulates around critical components, even though cooler air is present within the overall enclosure.

The image illustrates the limitations of conventional PSU designs, where the lack of internal structures to guide or concentrate airflow leads to indiscriminate cooling. The incoming air, typically drawn in by a fan, flows through the entire internal volume without specific redirection, meaning that much of the airflow bypasses the hottest areas and dissipates in less critical zones. As shown in FIG. 2, this results in suboptimal thermal management, where the components most prone to overheating do not receive the accelerated, concentrated airflow they require for effective heat dissipation. The thermal field further demonstrates that despite the operation of an internal cooling mechanism, the inability to guide the airflow contributes to thermal stress on essential components, which can compromise the PSU's long-term reliability and efficiency.

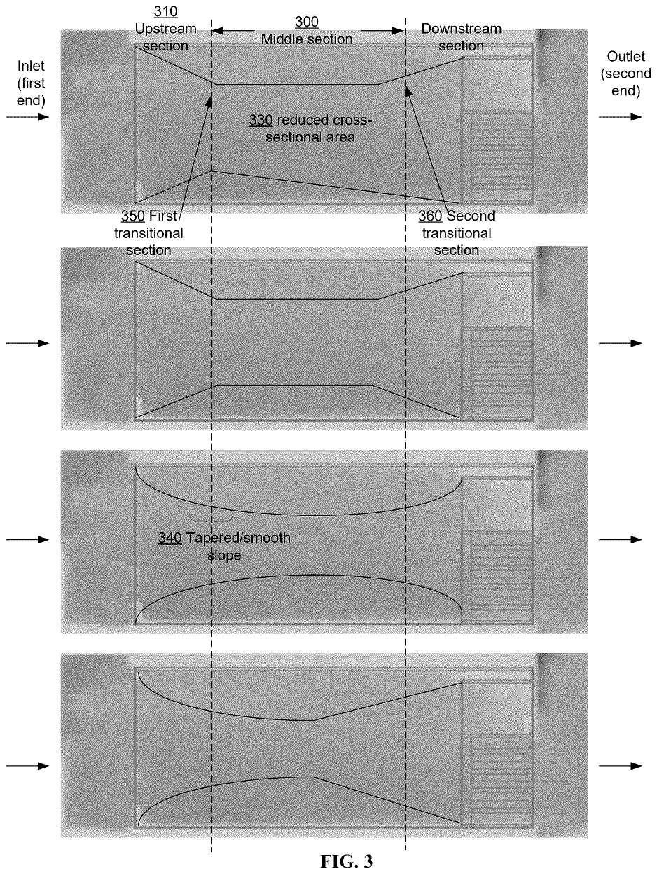

FIG. 3 illustrates a plurality of airflow guiding structures inside a PSU for improving heat dissipation efficiency inside the PSU, according to one example embodiment.

Although the specific structures illustrated in FIG. 3 differ slightly, they share common features. The PSU includes a housing with an air inlet at the first end for receiving cooling air and an air outlet at the second end for expelling heated air. While the external shape of the housing remains substantially rectangular or cuboid, consistent with conventional PSU designs, the internal structure incorporates a mid-section 300 with a reduced cross-sectional area 330 relative to the adjacent upstream 310 and downstream sections 320. This narrowed airflow path in the mid-section 330 is formed by an internal partition or a contoured structure that physically constricts the cross-sectional area of the airflow channel.

In particular, the internal structure works as an airflow guiding structure that creates a constriction in the mid-section 330, which accelerates the airflow as it passes through, based on the fluid flow equation Q=A×V, where Q is the flow rate, A is the cross-sectional area, and V is the velocity. Since the cross-sectional area decreases at the mid-section 330, the velocity of the airflow increases, enabling more effective removal of heat from the PSU's heat-generating components. In this embodiment, at least one primary heat-generating component, such as a transformer, voltage regulator, or power conversion module, may be positioned within or proximate to the mid-section 330 where the airflow velocity is highest. This targeted placement ensures that the accelerated airflow is directed precisely to the components most prone to heat buildup, enhancing cooling efficiency

In some embodiments, the constriction in the mid-section 330 may be formed by an internal partition added during the assembly process or by a molded structure integrated into the housing during manufacturing. This flexibility in design allows for cost-effective implementation while ensuring that the airflow is channeled effectively through the PSU.

Additionally, FIG. 3 illustrates how the airflow transitions from the constricted mid-section 330 into the downstream section, where the cross-sectional area expands again. This gradual expansion allows the accelerated air to diffuse smoothly, minimizing backpressure and enhancing overall airflow efficiency. The downstream expansion also aids in dissipating the residual heat before the air exits the PSU through the outlet.

In some embodiments, the PSU includes a fan positioned near the air inlet (or near the air outlet) to generate the airflow through the PSU housing. Due to the presence of a mid-section 330 having a reduced cross-sectional area relative to the adjacent upstream and downstream sections, the airflow velocity increases as it passes through the mid-section 330. This accelerated airflow enables more effective cooling of heat-generating components positioned within or proximate to the mid-section 330. As a result, the fan is configured to operate at a lower rotational speed than a fan in a comparable power supply unit lacking such a reduced cross-sectional mid-section 330. The ability to achieve enhanced convective cooling without requiring high fan speeds lowers operational noise levels and decreases energy consumption, thereby enabling quieter and more energy-efficient operation while maintaining thermal conditions within a safe range. By optimizing the internal airflow path through aerodynamic shaping of the housing, the design not only prevents overheating and thermal stress but also prolongs the lifespan of heat-sensitive components and supports higher power densities, making the PSU suitable for computing-intensive applications that demand higher performance.

Referring back to the specific structures illustrated in FIG. 3, these structures are implemented using either an internal partition, a contoured structure, or a molded structure integrated during manufacturing. Regardless of the specific implementation, all examples feature a smooth and continuous transition from a larger cross-sectional area upstream (or upstream section 310), through a narrower mid-section 330, and then back to a larger cross-sectional area downstream (or downstream section 320). This aerodynamic design minimizes turbulence, reduces pressure loss, and optimizes airflow velocity, thereby improving heat dissipation efficiency.

In some embodiments, the first transition section 350, which reduces the cross-sectional area from the upstream region to the narrower mid-section 330, utilizes a tapered structure 340 with a smooth slope. This tapering ensures a gradual narrowing of the airflow path, preventing abrupt changes that could otherwise create turbulence and reduce aerodynamic efficiency. For example, the tapered structure 340 may take the form of a conical shape with a circular cross-section, where the diameter decreases progressively as the airflow approaches the mid-section.

In another example, the tapered structure 340 in the first transition section may have a trapezoidal or frustum shape with a rectangular cross-section. This configuration gradually reduces the width and/or height of the airflow channel, making it suitable for PSUs with rectangular internal geometries or components aligned along planar surfaces. Both the conical and trapezoidal embodiments are designed to guide the cooling air efficiently toward the mid-section while maintaining a streamlined flow.

In some embodiments, the second transition section 360, positioned downstream from the narrower mid-section, employs an expanding structure with a smooth and continuous slope to gradually increase the cross-sectional area of the airflow channel. This expansion allows the accelerated airflow exiting the mid-section to decelerate smoothly, minimizing backpressure and promoting efficient heat dispersion before the air is expelled through the outlet. The expanding structure can mirror the shape of the tapered structure in the first transition section, such as a conical expansion for circular cross-sections or a frustum-shaped expansion for rectangular cross-sections. Alternatively, the shape of the expanding structure may differ, depending on the specific thermal and aerodynamic requirements of the PSU.

The embodiments of the airflow guiding structures illustrated in FIG. 3 may be installed or manufactured inside a PSU, which can be integrated into a larger computing system or server. In an example implementation, the computing system or server includes a chassis that houses the PSU, a processor, and other internal components. A system fan may be positioned to drive airflow through the PSU housing. The PSU includes an air inlet near the front portion of the chassis and an air outlet toward the rear, with an upstream section, a mid-section having a reduced cross-sectional area, and a downstream section. The narrowed mid-section increases airflow velocity and directs the accelerated airflow toward at least one heat-generating component positioned within or proximate to the mid-section.

In some embodiments, the specially designed airflow-guiding structures may be selectively positioned or tailored for integration in systems where specific components generate particularly high thermal loads. For example, power conversion modules, high-capacity voltage regulators, or transformer coils in the PSU may demand concentrated cooling due to localized heat accumulation. Similarly, in high-performance computing systems, critical workloads running on multi-core CPUs, GPUs, FPGAs, or AI accelerators may create significant heat buildup near the PSU. The airflow-enhancing mid-section can be configured or aligned to correspond to the locations of these high-heat-generating components, ensuring that the most thermally demanding areas receive the highest velocity cooling airflow.

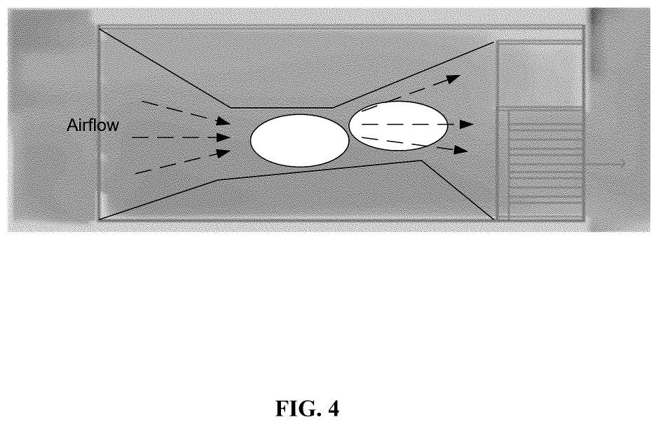

FIG. 4 illustrates an example airflow guiding structure inside a PSU for improving heat dissipation efficiency over key heat-generating components, according to one example embodiment. The two oval shapes in FIG. 4 represent two key heat-generating components. To achieve optimal cooling, an internal structure guides the incoming airflow through a narrow mid-section situated just upstream of the first heat-generating component. This narrow mid-section extends to cover the second heat-generating component, ensuring that both components are exposed to a higher-velocity stream of cooling air.

By creating this constricted region in the middle of the PSU, the airflow accelerates as it passes through. This acceleration effectively concentrates the cooling potential around the components that generate the most heat.

The shape and positioning of the mid-section can be tailored to the specific arrangement of internal parts, making it particularly suitable for PSUs where the primary heat sources are placed in irregular locations. By targeting these key areas with intensified airflow, the design in FIG. 4 reduces localized hotspots, thus improving both operational reliability and overall thermal performance of the PSU.

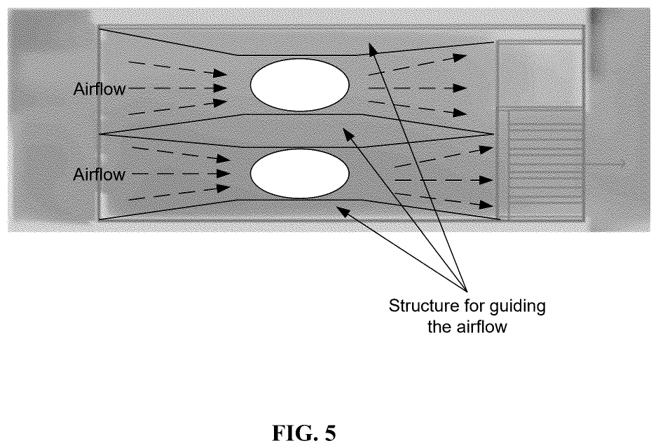

FIG. 5 illustrates another example airflow guiding structure inside a PSU for improving heat dissipation efficiency over key heat-generating components, according to one example embodiment. In FIG. 5, the two oval shapes again represent critical components, although their placement differs from that shown in FIG. 4. Instead of being positioned one after the other along a single airflow path, these components in FIG. 5 are situated more remotely from one another and arranged in parallel within the mid-section of the PSU. To target each component effectively, two separate airflow paths are formed: a top path and a bottom path, both sharing an elongated barrier that runs through the central portion of the PSU.

In operation, the incoming air in both airflow paths follows “wider, narrower, and wider” pattern. The air initially enters a relatively broad region, then narrows to accelerate as it passes around the heat-generating component, and finally expands again downstream to facilitate heat dispersion. By shaping and confining each path with the elongated barrier in the center, the airflow can be directed more precisely to the components located in each path, ensuring that both benefit from intensified cooling where it is most needed.

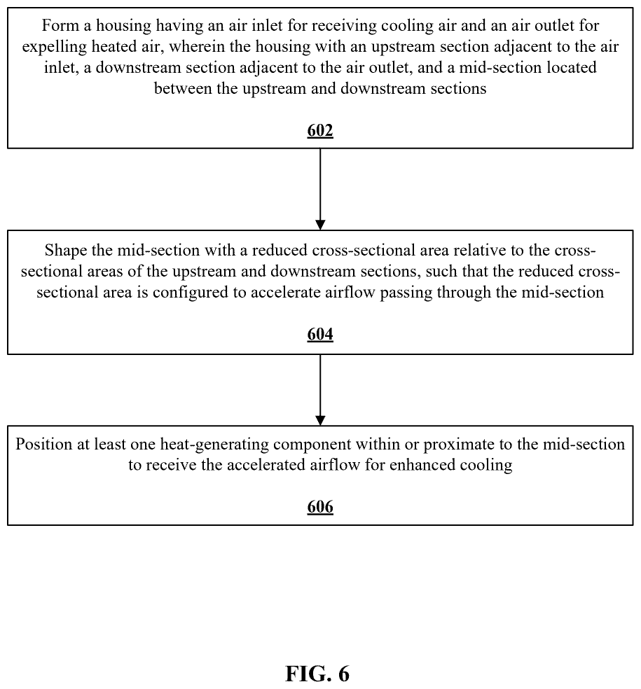

FIG. 6 is an example manufacturing process 600 of the PSU, in accordance with some embodiments. In some implementations, one or more process blocks of FIG. 6 may be performed by a device.

As shown in FIG. 6, process 600 may include forming a housing having an air inlet for receiving cooling air and an air outlet for expelling heated air, where the housing includes an upstream section adjacent to the air inlet, a downstream section adjacent to the air outlet, and a mid-section located between the upstream and downstream sections (block 602). For example, the device may form the housing with this structure, as described above.

Process 600 may further include forming the mid-section with a reduced cross-sectional area relative to the upstream and downstream sections, such that the reduced cross-sectional area is configured to accelerate airflow passing through the mid-section (block 604). For example, the device may form the mid-section to have a smaller cross-sectional area in order to increase airflow velocity, as previously described.

Additionally, process 600 may include positioning at least one heat-generating component within or proximate to the mid-section to receive the accelerated airflow for enhanced cooling (block 606). For instance, the device may place a heat-generating component such as a voltage regulator or power conversion module near the mid-section, where airflow is most concentrated, to improve thermal dissipation.

Process 600 may include additional variations or enhancements, including any single implementation or any combination of implementations described below or in connection with other processes elsewhere herein.

In a first implementation, forming the mid-section with a reduced cross-sectional area may include incorporating an internal partition or a contoured structure within the housing.

In a second implementation, which may be used alone or in combination with the first, forming the mid-section may include molding the mid-section as an integrated portion of the housing during manufacturing.

In a third implementation, alone or in combination with one or more of the first two, process 600 may include installing a fan configured to generate airflow through the housing.

In a fourth implementation, which may be combined with any of the first three, the fan is selected or configured to operate at a lower rotational speed than a fan in a comparable power supply unit lacking a mid-section with a reduced cross-sectional area. The increased airflow velocity through the mid-section reduces operational noise and improves energy efficiency while maintaining acceptable thermal conditions.

In a fifth implementation, alone or in combination with any of the first through fourth, process 600 may further include forming a transition section from the upstream section to the mid-section. The transition section includes a tapered structure with a smooth and continuous slope configured to gradually narrow the airflow path, minimizing turbulence, reducing pressure loss, and optimizing airflow velocity.

In a sixth implementation, alone or in combination with any of the first through fifth, process 600 may further include forming a transition section from the mid-section to the downstream section. This transition section includes an expanding structure with a smooth and continuous slope that gradually increases the cross-sectional area to facilitate airflow diffusion, reduce backpressure, and enhance heat dispersion efficiency.

Although FIG. 6 shows example blocks of process 600, in some implementations, process 600 may include additional blocks, fewer blocks, different blocks, or differently arranged blocks than those depicted. Additionally, two or more of the blocks may be performed in parallel.

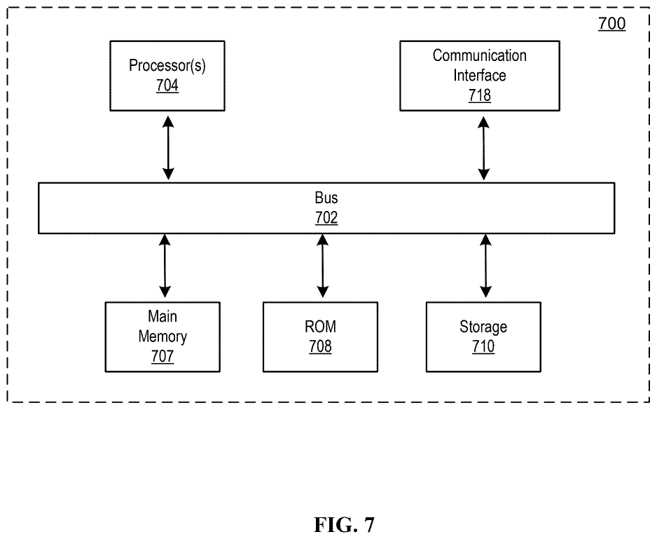

FIG. 7 depicts a block diagram of an example computer system 700 in which various of the embodiments described herein may be implemented. The computer system 700 includes a bus 702 or other communication mechanism for communicating information, one or more hardware processors 704 coupled with bus 702 for processing information. Hardware processor(s) 704 may be, for example, one or more general purpose microprocessors.

The computer system 700 also includes a main memory 707, such as a random-access memory (RAM), cache and/or other dynamic storage devices, coupled to bus 702 for storing information and instructions to be executed by processor 704. Main memory 707 also may be used for storing temporary variables or other intermediate information during execution of instructions to be executed by processor 704. Such instructions, when stored in storage media accessible to processor 704, render computer system 700 into a special-purpose machine that is customized to perform the operations specified in the instructions.

The computer system 700 further includes a read only memory (ROM) 708 or other static storage device coupled to bus 702 for storing computer instructions for processor 704. A storage device 710, such as a magnetic disk, optical disk, or USB thumb drive (Flash drive), etc., is provided and coupled to bus 702 for storing information and instructions.

The computing system 700 may include a user interface module to implement a GUI that may be stored in a mass storage device as executable software codes that are executed by the computing device(s). This and other modules may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables.

The foregoing description of the present disclosure has been provided for the purposes of illustration and description. It is not intended to be exhaustive or to limit the disclosure to the precise forms disclosed. The breadth and scope of the present disclosure should not be limited by any of the above-described exemplary embodiments. Many modifications and variations will be apparent to the practitioner skilled in the art. The modifications and variations include any relevant combination of the disclosed features. The embodiments were chosen and described in order to best explain the principles of the disclosure and its practical application, thereby enabling others skilled in the art to understand the disclosure for various embodiments and with various modifications that are suited to the particular use contemplated. It is intended that the scope of the disclosure be defined by the following claims and their equivalence.

What is claimed is:

1. A power supply unit (PSU), comprising:
a housing defining an air inlet for receiving cooling air and an air outlet for expelling heated air,
wherein the housing comprises an upstream section close to the air inlet, a downstream section close to the air outlet, and a mid-section having a reduced cross-sectional area relative to cross-sectional areas of the upstream section and the downstream section,
the reduced cross-sectional area of the mid-section accelerates an airflow passing through the mid-section, and
at least one heat-generating component is positioned within or proximate to the mid-section to receive the accelerated airflow for enhanced cooling.

2. The PSU of claim 1, wherein the reduced cross-sectional area is formed by an internal partition or a contoured structure within the housing.

3. The PSU of claim 1, wherein the mid-section is formed by a molded structure integrated into the housing during manufacturing.

4. The PSU of claim 1, wherein the housing has an external shape that is substantially rectangular or cuboid.

5. The PSU of claim 1, further comprising a fan configured to generate the airflow through the housing.

6. The PSU of claim 5, wherein the fan is configured to operate at a lower rotational speed than a fan in a comparable power supply unit lacking a mid-section with a reduced cross-sectional area, wherein the reduced cross-sectional area in the mid-section increases airflow velocity through the mid-section, thereby reducing operational noise and improving energy efficiency while maintaining thermal conditions.

7. The PSU of claim 1, wherein a transition section from the upstream section to the mid-section comprises:
a tapered structure with a smooth and continuous slope, configured to gradually narrow a cross-sectional area of the airflow to minimize turbulence and improve aerodynamic efficiency, thereby reducing pressure loss and optimizing airflow velocity.

8. The PSU of claim 7, wherein the tapered structure defining the transition section comprises a conical shape with a circular cross-section that gradually narrows toward the mid-section.

9. The PSU of claim 7, wherein the tapered structure defining the transition section comprises a trapezoidal or frustum shape with a rectangular cross-section that gradually narrows toward the mid-section.

10. The PSU of claim 1, wherein a transition section from the mid-section to the downstream section comprises:
an expanding structure with a smooth and continuous slope that gradually increases a cross-sectional area to facilitate airflow diffusion, reduce backpressure, and enhance heat dispersion efficiency.

11. A housing for a power supply unit (PSU), comprising:
an air inlet positioned at a first end of the housing to receive cooling air;
an air outlet positioned at a second end of the housing to expel heated air;
an upstream section extending from the first end of the housing toward a mid-section;
a downstream section extending from the mid-section toward the second end of the housing;
the mid-section located between the upstream section and the downstream section, the mid-section having a reduced cross-sectional area that is smaller than cross-sectional areas of the upstream second and downstream section of the housing;
wherein the reduced cross-sectional area of the mid-section is configured to increase an airflow velocity through the mid-section relative to the upstream and downstream sections, thereby enhancing convective heat transfer in the mid-section.

12. The housing of claim 11, wherein the mid-section is defined by an internal partition or a contoured structure integrated into the housing.

13. The housing of claim 11, wherein the mid-section is formed by a molded structure fabricated during housing manufacturing.

14. The housing of claim 11, wherein an external shape of the housing is substantially rectangular or cuboid.

15. The housing of claim 11, further comprising a fan mounted within the housing and configured to drive airflow from the air inlet through the mid-section to the air outlet.

16. The housing of claim 15, wherein the fan is configured to operate at a lower rotational speed than a fan in a comparable housing lacking a reduced cross-sectional area in the mid-section, wherein the reduced cross-sectional area in the mid-section increases airflow velocity through the mid-section, thereby reducing operational noise and improving energy efficiency while maintaining thermal conditions.

17. The housing of claim 11, wherein a transition section between the upstream section and the mid-section comprises a tapered structure with a smooth and continuous slope that narrows the cross-sectional area to minimize turbulence and optimize airflow.

18. The housing of claim 17, wherein the tapered structure comprises a conical shape having a circular cross-section that gradually narrows toward the mid-section.

19. The housing of claim 17, wherein the tapered structure comprises a trapezoidal or frustum shape having a rectangular cross-section that gradually narrows toward the mid-section.

20. A computing system, comprising:
a chassis;
a processor mounted within the chassis;
a power supply unit (PSU) mounted within the chassis; and
a fan configured to drive an airflow through the PSU;
wherein the PSU comprises:
a housing comprising an air inlet for receiving cooling air and an air outlet for expelling heated air;
the housing further comprising an upstream section close to the air inlet, a downstream section close to the air outlet, and a mid-section having a reduced cross-sectional area relative to cross-sectional areas of the upstream section and the downstream section,
wherein the reduced cross-sectional area of the mid-section accelerate the airflow through the mid-section, and
wherein at least one heat-generating component is positioned within or proximate to the mid-section to receive the accelerated airflow for enhanced cooling.
